(19) United States
(12) Patent Application Publication
(10) Pub. No.: US 2024/0407229 A1
(43) Pub. Date: Dec. 5, 2024

(54) DISPLAY DEVICE

(71) Applicant: Sharp Display Technology Corporation, Kameyama City, Mie (JP)

(72) Inventor: Makoto KITAGAWA, Kameyama City, Mie (JP)

(21) Appl. No.: 18/700,199

(22) PCT Filed: Dec. 20, 2021
(86) PCT No.: PCT/JP2021/047083

§ 371 Date: Apr. 10, 2024

(51) Int. Cl. H10K 59/80

(52) U.S. Cl. CPC H10K 59/8723

(57) ABSTRACT

An organic EL display device includes an array substrate provided with a plurality of organic EL elements, a counter substrate facing the array substrate, and a sealing member configured to bond together the array substrate and the counter substrate. The sealing member includes, between the array substrate and the counter substrate, a dam member disposed surrounding a display region and a fill member filling a sealed space surrounded by the dam member. A panel body formed by bonding together the array substrate and the counter substrate includes a partition wall configured to partition the dam member and the fill member and a plurality of spacers configured to maintain a gap between the array substrate and the counter substrate.

### TECHNICAL FIELD

The disclosure relates to a display device.

### BACKGROUND ART

In recent years, organic electro luminescence (hereinafter, referred to as EL) display devices using organic EL elements have been used as light-emitting elements in practical applications. Also, development in continuing for quantum-dot light emitting diode (QLED) display devices provided with QLEDs that are light-emitting elements using a quantum dot-including layer. Organic EL display devices and QLED display devices have a sealing structure in which a plurality of light-emitting elements constituting a display region are covered with a sealing member having barrier properties in order to suppress deterioration of the plurality of light-emitting elements due to moisture, oxygen, and the like entering. A known sealing structure for such a light-emitting element includes a dam fill structure. A dam fill structure is disclosed in PTL 1, for example.

An organic EL display device (OLED display panel) of PTL 1 includes a first substrate and a second substrate facing one another and a dam member (first package gel), a fill member (second package gel), and a cover wall provided between the first substrate and the second substrate. The dam member is formed around the sealed space between the first substrate and the second substrate. The fill member fills the sealed space formed by the dam member. A plurality of the cover walls are provided on the first substrate aligned with the dam member in the sealed space.

### CITATION LIST

### Patent Literature

PTL 1: CN 105609660

### SUMMARY OF INVENTION

### Technical Problem

In the dam fill structure as disclosed in PTL 1, adjacent cover walls are disposed with a gap therebetween. Further, a gap is provided between each cover wall and the second substrate. Thus, if the pressure when bonding together the first substrate and the second substrate with the dam member and the fill member therebetween is high, the speed of the fill member when spreading from the central side to the outer peripheral side increases when the fill member spreads between adjacent cover walls and the gaps between the cover walls and the second substrate. Thus, the fill member may push out the dam member from the inside and cause it to break.

In addition, it is difficult to make the gap between the first substrate and the second substrate constant when the two substrates are bonded together. Thus, the volume of the sealed space surrounded by the dam member between the first substrate and the second substrate is not constant. When the amount of the fill member is large with respect to the volume of the sealed space in which the variation is likely to occur, the fill member may cause the dam member to break. On the other hand, when the amount of the fill member is small with respect to the volume of the sealed space, there is a possibility of air bubbles formed inside the sealed space. When the dam member breaks or air bubbles are formed in the sealed space, the sealing properties of the light-emitting element from the dam fill structure are impaired.

An object of the disclosure is to suppress impairment of the sealing properties of a light-emitting element from a dam fill structure in a display device.

### Solution to Problem

A target of the technique according to the disclosure is a display device. A display device according to a technique of the disclosure includes a first substrate provided with a plurality of light-emitting elements;
a second substrate disposed facing the first substrate; and a sealing member configured to bond together the first substrate and the second substrate and seal the plurality of light-emitting elements. The display device includes a display region for displaying an image by light emission of the plurality of light-emitting elements and a frame region provided on an outer side the display region. The sealing member includes, between the first substrate and the second substrate, a dam member disposed in the frame region surrounding the display region and a fill member filling the space surrounded by the dam member. A panel body formed by bonding together the first substrate and the second substrate with the sealing member includes a partition wall configured to partition the dam member and the fill member and a plurality of spacers disposed in a spread-out manner in the display region and configured to maintain a gap between the first substrate and the second substrate.

### Advantageous Effects of Invention

According to a technique of the disclosure, impairment of the sealing properties of a light-emitting element from a dam fill structure in a display device can be suppressed.

### BRIEF DESCRIPTION OF DRAWINGS

FIG. 1 is a plan view illustrating a schematic configuration of an organic EL display device according to a first embodiment.

FIG. 2 is a cross-sectional view of the organic EL display device taken along a line II-II in FIG. 1.

FIG. 3 is a plan view partially illustrating a display region of the organic EL display device according to the first embodiment.

FIG. 4 is a cross-sectional view of the organic EL display device taken along a line IV-IV in FIG. 3.

FIG. 5 is a cross-sectional view illustrating a preparation process of an array substrate of the first embodiment.

FIG. 6 is a plan view illustrating a schematic configuration of the array substrate of the first embodiment.

FIG. 7 is a cross-sectional view of the array substrate taken along a line VII-VII in FIG. 6.

FIG. 8 is a cross-sectional view illustrating a preparation process of a counter substrate of the first embodiment.

FIG. 9 is a plan view illustrating a schematic configuration of the counter substrate of the first embodiment.

FIG. 10 is a cross-sectional view of the counter substrate taken along a line X-X in FIG. 9.

FIG. 11 is a plan view illustrating how a dam member and a fill member are applied to a counter substrate in the manufacture of the organic EL display device of the first embodiment.

FIG. 12 is a cross-sectional view illustrating how the array substrate and the counter substrate are bonded together in the manufacture of the organic EL display device of the first embodiment.

FIG. 13 is a plan view illustrating a schematic configuration of an organic EL display device according to a second embodiment.

FIG. 14 is a cross-sectional view illustrating a main portion of the organic EL display device with the cross section taken in a direction along a screen at a portion circled by a line XIV in FIG. 13.

FIG. 15 is a plan view illustrating a schematic configuration of the array substrate of the second embodiment.

FIG. 16 is a plan view illustrating a schematic configuration of the counter substrate of the second embodiment.

FIG. 17 is a cross-sectional view of a portion corresponding to FIG. 2 of an organic EL display device of a third embodiment.

FIG. 18 is a cross-sectional view illustrating a main portion of the organic EL display device circled by a line XVIII in FIG. 17.

FIG. 19 is a cross-sectional view of a portion corresponding to FIG. 2 of an organic EL display device of a fourth embodiment.

FIG. 20 is a cross-sectional view illustrating a main portion of the organic EL display device surrounded by a line XX in FIG. 19.

FIG. 21 is a cross-sectional view of a portion corresponding to FIG. 2 of an organic EL display device of a fifth embodiment.

FIG. 22 is a cross-sectional view illustrating how the array substrate and the counter substrate are bonded together in the manufacture of the organic EL display device of the fifth embodiment.

FIG. 23 is a cross-sectional view of a portion corresponding to FIG. 2 of an organic EL display device of a sixth embodiment.

FIG. 24 is a cross-sectional view illustrating how the array substrate and the counter substrate are bonded together in the manufacture of the organic EL display device of the sixth embodiment.

FIG. 25 is a plan view illustrating a schematic configuration of an organic EL display device according to a first modified example.

FIG. 26 is a cross-sectional view illustrating a main portion of the organic EL display device with the cross section taken in a direction along a screen at a portion circled by a line XXVI in FIG. 25.

FIG. 27 is a plan view illustrating a schematic configuration of an organic EL display device according to a second modified example.

FIG. 28 is a cross-sectional view illustrating a main portion of the organic EL display device with the cross section taken in a direction along a screen at a portion circled by a line XXVIII in FIG. 27.

FIG. 29 is a plan view partially illustrating a display region of the organic EL display device according to another embodiment.

FIG. 30 is a cross-sectional view of the organic EL display device taken along a line XXX-XXX in FIG. 29.

### DESCRIPTION OF EMBODIMENTS

Exemplary embodiments will be described below in detail with reference to the drawings. In the embodiments described below, an organic EL display device is described as an example of a display device according to a technique of the disclosure. Note that the drawings are for schematically describing the techniques of the disclosure. Thus, in the drawings, the dimensions, ratios, and numbers may be exaggerated or simplified to facilitate understanding of the techniques of the disclosure.

In the following embodiments, a “row direction” means the horizontal direction of a screen of a display device. The “row direction” corresponds to a first direction. A “column direction” means a vertical direction of the screen of the display device. The “column direction” corresponds to a second direction. A row of constituent elements such as subpixels means a horizontal arrangement of a plurality of constituent elements forming a line in the row direction. A column of constituent elements such as subpixels means a vertical arrangement of a plurality of constituent elements forming a line in the column direction.

In the following embodiments, the description that a constituent element such as another film, layer, or element is provided or formed on a constituent element such as a certain film, layer, or element does not mean only a case where another constituent element is present immediately above the certain constituent element but also includes a case where a constituent element such as still another film, layer, or element is interposed between both the constituent elements.

In the following embodiments, the description that a constituent element such as a certain film, layer, or element is connected to a constituent element such as another film, layer, or element means that the certain film, layer, or element is electrically connected unless otherwise specified. This description includes, without departing from the gist of the technique of the disclosure, not only a case in which a constituent element is directly connected to another constituent element but also a case in which a constituent element and another constituent element are indirectly connected to each other with still another constituent element such as still another film, layer, element, or the like interposed therebetween. The description also includes a case where another constituent element is integrated with a certain constituent element, that is, a part of the certain constituent element constitutes the other constituent element.

In the following embodiments, a description that a constituent element such as a certain film, layer, or element is in the same layer as a constituent element such as another film, layer, or element means that the certain constituent element is formed by the same process as that of the other constituent element. A description that a constituent element is in a lower layer below a constituent element means that the certain constituent element is formed by a process earlier than that of the other constituent element. A description that a constituent element is in an upper layer above a constituent element means that the certain constituent element is formed by a process later than that of the other constituent element.

In the following embodiments, the description that a constituent element such as a certain film, layer, or element is the same as or equivalent to a constituent element such as another film, layer, or element does not only mean a state where the certain constituent element is completely the same as or completely equivalent to the other constituent element, an also includes a state where the certain constituent element is substantially the same as or substantially equivalent to the other constituent element, such as a state where the certain constituent element and the other constituent element vary within a range of manufacturing modified examples or tolerances.

In the following embodiments, the descriptions of first, second, third, . . . are used to distinguish the words and phrases to which these descriptions are given, and no limitation with regard to the number and order of the words and phrases is intended.

### First Embodiment

An organic EL display device 1 of the first embodiment is used as a display in various devices such as a mobile phone including multifunctional mobile phones such as smartphones and tablet terminals, a personal computer (PC), and a television device.

### Configuration of Organic EL Display Device

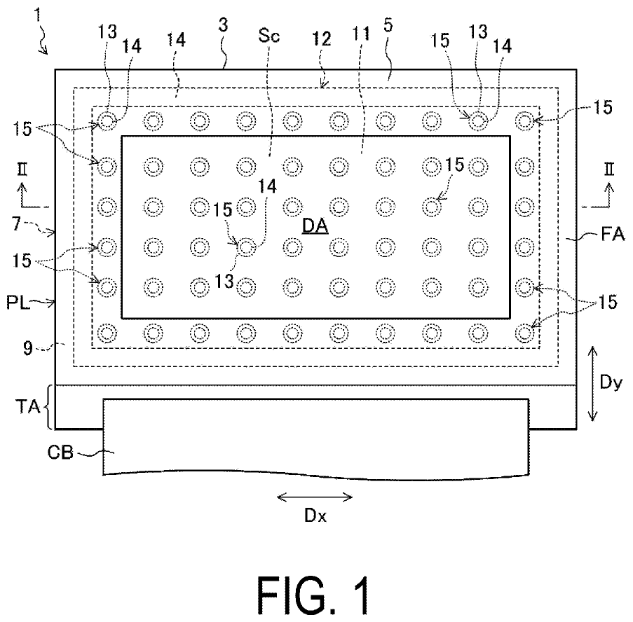

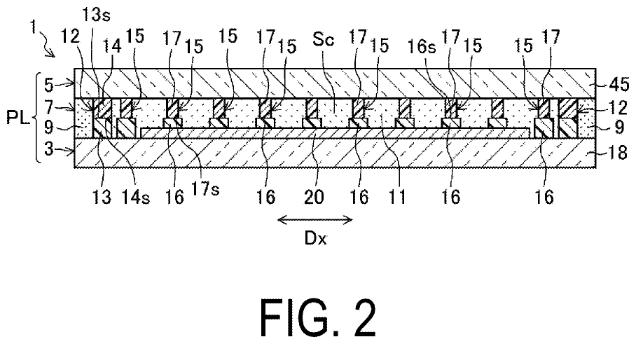

As illustrated in FIGS. 1 and 2, the organic EL display device 1 includes an array substrate 3, a counter substrate 5, and a sealing member 7. The array substrate 3 is an example of a first substrate. The array substrate 3 includes a plurality of organic electroluminescence elements (organic EL elements) 30. The counter substrate 5 is an example of a second substrate. The array substrate 3 and the counter substrate 5 are disposed facing one another. The array substrate 3 and the counter substrate 5 are bonded together via the sealing member 7 and form a panel body PL.

The sealing member 7 includes a dam member 9 and a fill member 11. The dam member 9 is disposed on the outer peripheral side of a frame region FA around a display region DA between the array substrate 3 and the counter substrate 5. A sealed space Sc surrounded by the dam member 9 is formed between the array substrate 3 and the counter substrate 5. The fill member 11 is filled in the sealed space Sc and fills the air gap between the array substrate 3 and the counter substrate 5.

The dam member 9 and the fill member 11 bond the array substrate 3 and the counter substrate 5 to seal the plurality of organic EL elements 30. Both the dam member 9 and the fill member 11 are made of an organic resin material. The organic resin material used for the dam member 9 and the fill member 11 is, for example, an epoxy resin, and has a photo-curable properties in that it is cured by irradiation of ultraviolet light or the like. The barrier properties of the dam member 9 with respect to moisture and oxygen is better than the barrier properties of the fill member 11 with respect to moisture and oxygen. As the organic resin material used for the dam member 9 and the fill member 11, an acrylic resin, a silicone resin, a fluorine resin, or the like may be used.

The panel body PL is provided with a partition wall 12 and a plurality of spacers 15.

The partition wall 12 is a wall body that partitions the dam member 9 and the fill member 11 and dams up the fill member 11 together with the dam member 9. The partition wall 12 extends along the inner periphery of the dam member 9 and is located on the outer periphery of the fill member 11. The partition wall 12 of the present example is formed in a closed frame shape extending around the entire periphery of the frame region FA. The partition wall 12 is formed, for example, in a rectangular frame-like shape. The partition wall 12 is provided at least on the counter substrate 5.

The partition wall 12 of the present example is provided separately for the array substrate 3 and the counter substrate 5. The partition wall 12 is constituted by a first partition wall 13 and a second partition wall 14. The first partition wall 13 is the partition wall 12 provided on the array substrate 3. The second partition wall 14 is the partition wall 12 provided on the counter substrate 5. The first partition wall 13 and the second partition wall 14 are butted against one another in the direction in which the array substrate 3 and the counter substrate 5 face one another.

Each of the plurality of spacers 15 is a column-like member that maintains the gap between the array substrate 3 and the counter substrate 5. The plurality of spacers 15 are disposed in a spread-out manner in a predetermined pattern in the display region DA. The plurality of spacers 15 are disposed in a matrix shape at equal intervals, for example. Each spacer 15 is provided on one or both of the array substrate 3 and the counter substrate 5 where the partition wall 12 is provided.

Each spacer 15 of the present example is provided separately for the array substrate 3 and the counter substrate 5. Each spacer 15 is constituted by a first spacer 16 and a second spacer 17. The first spacer 16 is the spacer 15 provided on the array substrate 3. The second spacer 17 is the spacer 15 provided on the counter substrate 5. The first spacer 16 and the second spacer 17 are butted against one another in the direction in which the array substrate 3 and the counter substrate 5 face one another.

The organic EL display device 1 includes a wiring line substrate CB in addition to the panel body PL. The wiring line substrate CB is a Flexible Printed Circuit (FPC), for example. The wiring line substrate CB is used to connect an external circuit such as a display control circuit to the panel body PL. The panel body PL includes the display region DA and the frame region FA.

The display region DA is a region for displaying an image and constitutes a screen. An image in the display region DA is displayed via light emission by the plurality of organic EL elements 30. The display region DA is provided in a rectangular shape. In the present embodiment, the display region DA having a rectangular shape is used as an example, but the display region DA may have a substantially rectangular shape such as a shape in which at least one side is arc-shaped, a shape in which at least one corner portion is arc-shaped, or a shape having a cutout in a part of at least one side.

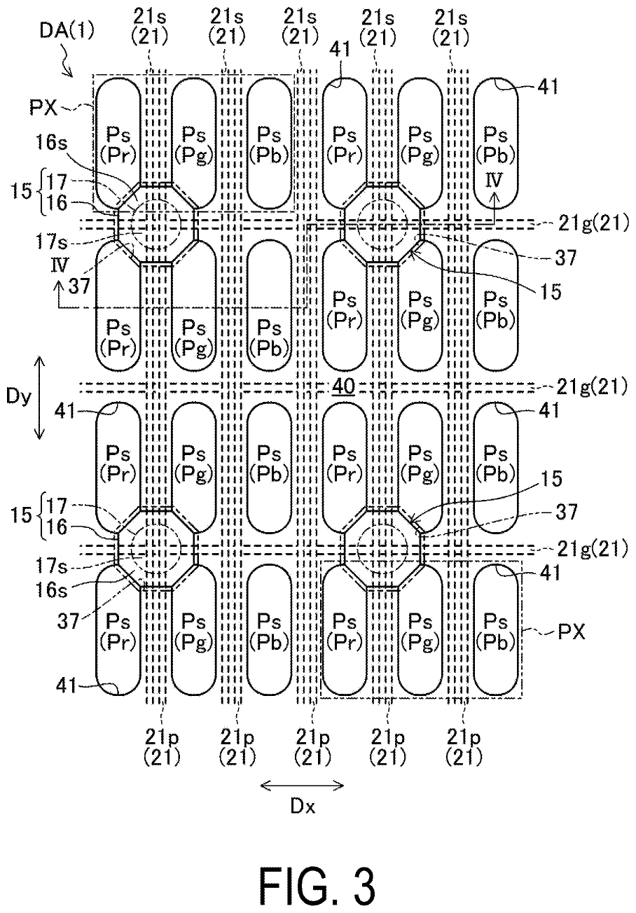

As illustrated in FIG. 3, the display region DA includes a plurality of pixels PX. The plurality of pixels Ps includes three subpixels. The three subpixels Ps correspond to, for example, a subpixel Pr that emits red light, a subpixel Pg that emits green light, and a subpixel Pb that emits blue light. The subpixels Pr, Pg, and Pb of the three colors forming each pixel PX of the present example are arranged in stripes adjacent to one another in the row direction.

The frame region FA is a region not for displaying an image and constitutes a non-display portion that is not a screen. The frame region FA is provided in a rectangular frame-like shape on the outer side of the display region DA. A portion constituting one side (lower side in FIG. 1) of the frame region FA constitutes a terminal region TA. The terminal region TA is provided in a region of the array substrate 3 protruding from the counter substrate 5 in a plan view. The wiring line substrate CB is connected to the terminal region TA.

Although not illustrated, a drive circuit is monolithically provided in the frame region FA. In the frame region FA, the drive circuit is disposed in portions constituting the sides (left and right sides in FIG. 1) adjacent to the side where the terminal region TA is provided. The drive circuit includes a gate driver. On the wiring line substrate CB, a source driver is mounted as an IC chip.

The frame region FA is further provided with a first frame line and a second frame line. The first frame line and the second frame line are provided on the array substrate 3 around the display region DA and extend to the terminal region TA. A high-level power supply voltage (ELVDD) is supplied to the first frame line via the wiring line substrate CB. A low-level power supply voltage (ELVSS) is supplied to the second frame line via the wiring line substrate CB.

### Array Substrate

As illustrated in FIG. 2, the array substrate 3 includes a base substrate 18 and an element layer 20.

The base substrate 18 is a plate body forming the base of the array substrate 3. The base substrate 18 is, for example, a glass substrate. The base substrate 18 may be formed of an organic resin material such as a polyimide resin, a polyamide resin, or an epoxy resin. The base substrate 18 may have a layered structure in which an inorganic insulating layer including an inorganic insulating material such as silicon oxide, silicon nitride, or silicon oxynitride and a resin layer including an organic resin material as described above are layered.

The element layer 20 includes various kinds of wiring lines 21. As illustrated in FIG. 3, a plurality of gate lines 21g, a plurality of source lines 21s, and a plurality of power source lines 21p are provided as the wiring lines 21.

Each of the plurality of gate lines 21g is a wiring line that transmits a gate signal. In the display region DA, the plurality of gate lines 21g extend in parallel to one another in a row direction Dx between the subpixels Ps adjacent to one another in a column direction Dy and are arranged at intervals in the column direction Dy. The gate lines 21g are provided per row of the subpixels Ps. Each of the gate lines 21g is connected to a gate driver included in the drive circuit.

Each of the plurality of source lines 21s is a wiring line that transmits a source signal. In the display region DA, the plurality of source lines 21s extend in parallel to one another in the column direction Dy between the subpixels Ps adjacent to one another in the row direction Dx and are arranged at intervals in the row direction Dx. The source lines 21s are provided per column of the subpixels Ps. Each source line 21s is connected to the source driver via the wiring line substrate CB.

Each of the plurality of power source lines 21p applies a predetermined high-level power supply voltage (ELVDD). In the display region DA, the plurality of power source lines 21p extend in parallel to one another in the column direction Dy between the subpixels Ps adjacent to one another in the row direction Dx and are arranged at intervals in the row direction Dy. The power source lines 21p are provided per row of the subpixels Ps. Each power source line 21p is connected to the first frame line.

The gate lines 21g, the power source lines 21p, and the source lines 21s intersect one another intermediated by an insulating film. The gate lines 21g, the source lines 21s, and the power source lines 21p extend in a lattice pattern as seen overall in a plan view. For example, the gate lines 21g, the source lines 21s, and the power source lines 21p are made of a metal such as aluminum (Al), tungsten (W), molybdenum (Mo), tantalum (Ta), chromium (Cr), titanium (Ti), copper (Cu), or the like.

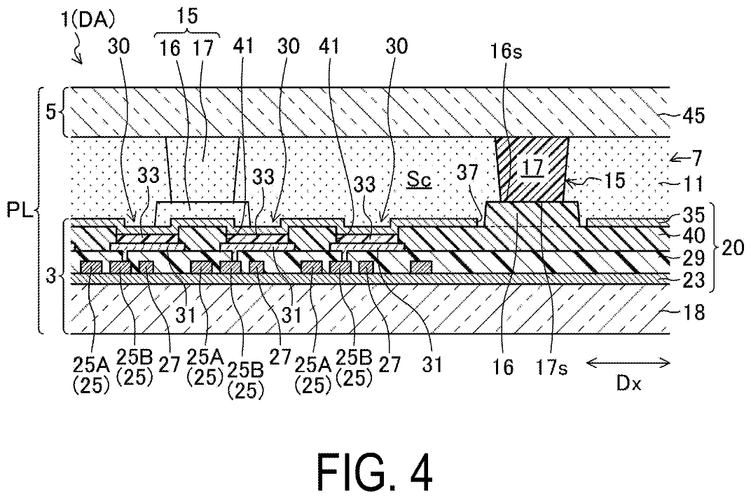

As illustrated in FIG. 4, the element layer 20 further includes a base coat film 23, a plurality of thin film transistors (hereinafter referred to as TFTs) 25, a plurality of capacitors 27, a flattening film 29, the organic EL elements 30, and an edge cover 40. The organic EL elements 30 are examples of light-emitting elements.

The base coat film 23 is provided over the entire front face of the base substrate 18. The base coat film 23 is formed of an inorganic insulating material such as silicon oxide, silicon nitride, or silicon oxynitride, for example. The base coat film 23 may be a single-layer film made of an inorganic insulating material or may be a layered film.

The plurality of TFTs 25 are elements for controlling light emission of the organic EL elements 30. Each TFT 25 is configured as a bottom gate type, for example. Although not illustrated, each TFT 25 includes a gate electrode, a first terminal electrode, and a second terminal electrode. The plurality of TFTs 25 include a first TFT 25A and a second TFT 25B. The first TFT 25A and the second TFT 25B are provided for each subpixel Ps.

The gate electrode of the first TFT 25A is connected to the corresponding gate line 21g. The first terminal electrode of the first TFT 25A is connected to the corresponding source line 21s. The gate electrode of the second TFT 25B is connected to the second terminal electrode of the first TFT 25A. The first terminal electrode of the second TFT 25B is connected to the power source line 21p. The second terminal electrode of the second TFT 25B is connected to the corresponding organic EL element 30 (pixel electrode 31).

Each of the plurality of capacitors 27 is an element for holding data. At least one capacitor 27 is provided for each subpixel Ps. Although not illustrated, the capacitor 27 includes a first capacitance electrode and a second capacitance electrode. The first capacitance electrode and the second capacitance electrode face one another with an insulating film therebetween. The first capacitance electrode is connected to the gate electrode of the first TFT 25A. The second capacitance electrode is connected to the second terminal electrode of the second TFT 25B.

The plurality of organic EL elements 30 are each configured as a top-emitting type that extract light produced by an organic EL layer 33 from the counter substrate 5 side. The organic EL element 30 includes the pixel electrode 31, the organic EL layer 33, and a common electrode 35.

The pixel electrode 31 is provided for each of the subpixels Ps. Each of the plurality of organic EL elements 30 includes the pixel electrode 31 individually. The pixel electrodes 31 are arranged in a matrix shape corresponding to the subpixels Ps. The pixel electrodes 31 are provided on the flattening film 29. The pixel electrodes 31 have light-reflecting characteristics. The pixel electrodes 31 function as an anode electrode. A conductive material having a large work function is preferably used for the pixel electrodes 31.

The edge cover 40 is provided to partition the plurality of pixel electrodes 31. The edge cover 40 is formed in a lattice pattern as a whole and covers a peripheral portion of each of the pixel electrodes 31. Openings 41 for respectively exposing the pixel electrodes 31 are formed in the edge cover 40. The edge cover 40 is made of, for example, an organic resin material such as a polyimide resin or an acrylic resin or a polysiloxane based SOG material or the like.

The organic EL layer 33 is provided on the individual pixel electrodes 31 in each opening 41 of the edge cover 40. The organic EL layer 33 includes a hole injection layer, a hole transport layer, a light-emitting layer, an electron transport layer, and an electron injection layer that are provided in order on the pixel electrode 31. These function layers are made of a known compound suitable for the respective function. One or more of the plurality of function layers may be continuously provided in common in the plurality of subpixels Ps.

The common electrode 35 is continuously provided in common to the plurality of subpixels Ps. The common electrode 35 is provided on the organic EL layer 33 covering the edge cover 40 and overlaps each of the pixel electrodes 31 via the organic EL layer 33. The common electrode 35 has light-transmitting characteristics. The common electrode 35 functions as a cathode electrode. A conductive material having a small work function is preferably used for the common electrode 35. The common electrode 35 extends to the frame region FA and is connected to the second frame line. As illustrated by the two-dot dash line in FIG. 3 for the sake of convenience, an opening 37 is formed in the common electrode 35 at a position corresponding to each first spacer 16.

The array substrate 3 further includes the first partition wall 13 and the plurality of first spacers 16 described above. The first partition wall 13 and each first spacer 16 are formed of the same material of the edge cover 40 and in the same layer.

The first partition wall 13 constitutes a half body obtained by dividing the partition wall 12 in the thickness direction of the panel body PL. The first partition wall 13 is formed to have the same height as that of each first spacer 16 on the array substrate 3. An abutting face 13s of the first partition wall 13 and an abutting face 16s of each first spacer 16 are aligned at the same height position in a planar direction orthogonal to the thickness direction of the array substrate 3.

Each first spacer 16 includes a projection formed by protruding portion of the edge cover 40. The projection portion is located in the opening 37 of the common electrode 35. The heights of the plurality of first spacers 16 are all equal to one another. The first spacers 16 are provided at intersection portions between the vertical line portions and the horizontal line portions of the edge cover 40. The area of the abutting face 16s of the first spacer 16 is larger than the area of an abutting face 17s of the second spacer 17. The abutting face 16s of the first spacer 16 functions as a seating face of the second spacer 17.

### Counter Substrate

As illustrated in FIG. 2, the counter substrate 5 includes a base substrate 45 and the second partition wall 14 and the plurality of second spacers 17 described above. The second partition wall 14 and each second spacer 17 are formed of the same material and in the same layer.

The base substrate 45 is a plate body corresponding to the base of the counter substrate 5. The base substrate 45 is, for example, a glass substrate. The base substrate 45 may be formed of an organic resin material such as a polyimide resin, a polyamide resin, or an epoxy resin. The base substrate 45 may have a layered structure in which an inorganic insulating layer including an inorganic insulating material such as silicon oxide, silicon nitride, or silicon oxynitride and a resin layer including an organic resin material as described above are layered.

The second partition wall 14 constitutes a half body obtained by dividing the partition wall 12 in the thickness direction of the panel body PL. The second partition wall 14 is formed to have the same height as that of each second spacer 17 on the counter substrate 5. An abutting face 14s of the second partition wall 14 and the abutting face 17s of each second spacer 17 are aligned at the same height position in a planar direction orthogonal to the thickness direction of the counter substrate 5.

The second spacers 17 are provided in a one-to-one correspondence with the first spacers 16 of the array substrate 3. Each second spacer 17 is located at a position corresponding to the first spacer 16. In other words, the second spacers 17 are disposed at intersection portions between the vertical line portions and the horizontal line portions of the edge cover 40. The heights of the plurality of second spacers 17 are all equal to one another. The plurality of second spacers 17 are separated from one another. The plurality of second spacers 17 may be constituted by projection portions of a resin film provided on the base substrate 45 and may be connected to one another at a lower portion of the resin film.

### Manufacturing Method of Organic EL Display Device

The manufacturing method of the organic EL display device 1 includes a first substrate preparing process, a second substrate preparing process, a bonding process, and an additional process.

### First Substrate Preparing Process

In the first substrate preparing process, the array substrate 3 is prepared. In order to prepare the array substrate 3, the base substrate 18, a glass substrate for example, is prepared and the element layer 20 including the plurality of TFTs 25, a plurality of organic EL elements 30, and a drive circuit is formed on the base substrate 18 using a known technique such as photolithography, a vacuum vapor deposition technique, an ink-jet method, or the like.

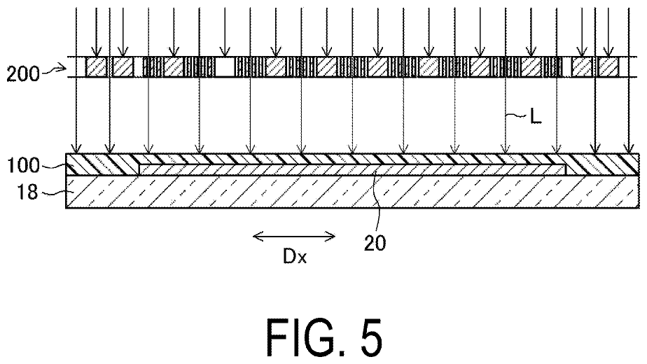

When the edge cover 40 is formed, a photosensitive resin material is applied on the substrate where the plurality of pixel electrodes 31 are formed by a known application method such as a spin coating method or a slit coating method (see FIG. 5; in FIG. 5, a portion corresponding to the element layer 20 with an unformed layer above the pixel electrode 31 is illustrated as the element layer 20 for the sake of convenience). As the photosensitive resin material, a positive-type or negative-type photoresist can be used. In the present example, as the photosensitive resin material, a positive-type photoresist is used. Next, an application film 100 of the photosensitive resin material is pre-baked at a predetermined temperature.

Subsequently, as illustrated in FIG. 5, an exposure treatment is performed on the application film 100 of the photosensitive resin material. In the exposure treatment, the application film 100 is irradiated with light L such as ultraviolet light using a photomask 200. The photomask 200 is configured to shield a pattern portion where the application film 100 is to remain and expose an unnecessary portion where the application film 100 is to be removed. In the exposure treatment of the present example, a graytone mask or a halftone mask is used as the photomask 200, the region of the application film 100 where the first partition wall 13 and the first spacers 16 are formed is shielded from light, and the region of the edge cover 40 where the portion other than the first spacers 16 is formed is exposed with a smaller amount of light than the portion where the first partition wall 13, the first spacers 16, and the edge cover 40 are not formed.

In a case where a negative-type photoresist is used as the photosensitive resin material forming the application film 100, in the exposure treatment, the photomask used is configured to expose a pattern portion where the application film 100 is to remain and to shield an unnecessary portion where the application film 100 is to be removed. In this case, a graytone mask or a halftone mask is used as the photomask, the region of the application film 100 where the first partition wall 12 and the first spacers 16 are formed is exposed to light, and the region of the edge cover 40 where the portion other than the first spacers 16 is formed is shielded from a smaller amount of light than the portion where the first partition wall 13, the first spacers 16, and the edge cover 40 are not formed.

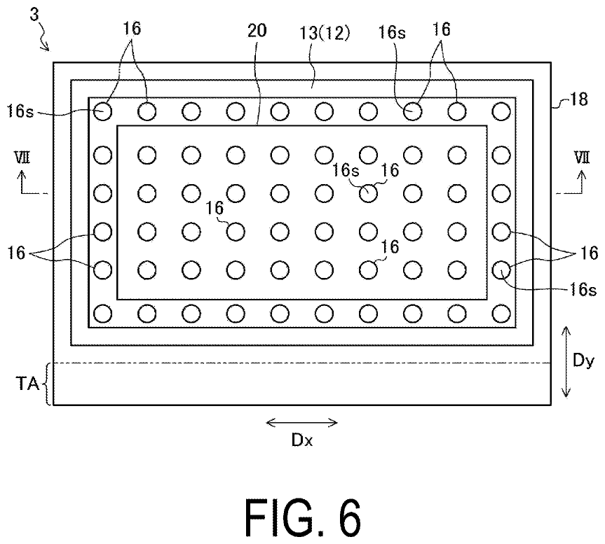

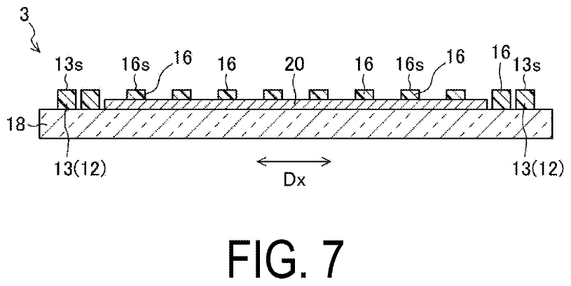

Subsequently, the application film 100 subjected to the exposure treatment is subjected to post-exposure baking to complete the photosensitive reaction of the photosensitive resin material forming the application film 100. Subsequently, a development treatment is performed on the application film 100 in which the photosensitive reaction is completed. In the development treatment, an alkaline developing solution such as tetramethylammonium hydroxide (TMAH) or potassium hydroxide (KOH) is used to dissolve an unnecessary portion of the application film 100 and leave only a pattern portion of the application film 100. Then, after cleaning with pure water, the substrate with the application film 100 partially left thereon is post-baked at a predetermined temperature to evaporate the solvent remaining on the substrate and completely cure the photoresist. In this manner, as illustrated in FIGS. 6 and 7, the first partition wall 13 and the plurality of first spacers 16 are formed on the base substrate 18 together with the element layer 20.

Thereafter, on the substrate where the first partition wall 13 and the like are formed, a conductive film is formed as a single layer or multilayer by an application method such as an ink-jet method or a slit coating method or a vacuum vapor deposition technique to form the common electrode 35. In a case where an ink-jet method is used, the common electrode 35 including the openings 37 can be formed by applying silver nanowires or the like so as not to cover the first spacers 16. In a case where a slit coating method or a vacuum vapor deposition technique is used, a photoresist is formed at a portion where the conductive film is to be left by screen printing or a lift-off method, the conductive film covering the first spacers 16 is removed by dry etching or wet etching, and then the photoresist is peeled off. In this manner, the conductive film is patterned and the common electrode 35 including the openings 37 is formed. If the thickness of the common electrode 35 is very thin and there is no problem in bonding the array substrate 3 and the counter substrate 5, the openings 37 may not be provided in the common electrode 35 (that is, the conductive film forming the common electrode 35 may not be patterned).

In this manner, the array substrate 3 is prepared.

### Second Substrate Preparing Process

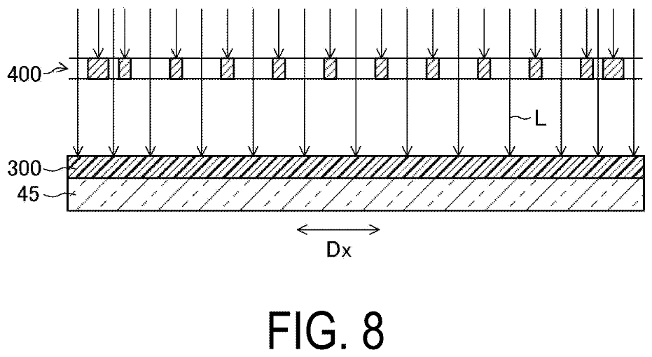

In the second substrate preparing process, the counter substrate 5 is prepared. In order to prepare the counter substrate 5, the base substrate 45, a glass substrate for example, is prepared, and a photosensitive resin material is applied onto the base substrate 45 by a known application method such as a spin coating method (see FIG. 8). As the photosensitive resin material, a positive-type or negative-type photoresist can be used. In the present example, as the photosensitive resin material, a positive-type photoresist is used. Next, an application film 300 of the photosensitive resin material is pre-baked at a predetermined temperature.

Subsequently, as illustrated in FIG. 8, an exposure treatment is performed on the application film 300 of the photosensitive resin material. In the exposure treatment, the application film 300 is irradiated with light L such as ultraviolet light using a photomask 400. The photomask 400 is configured to shield a pattern portion where the application film 300 is to remain and expose an unnecessary portion where the application film 100 is to be removed. In the exposure treatment of the present example, the region of the application film 100 where the second partition wall 14 and the second spacers 17 are formed is shielded from light and the other region is exposed.

In a case where a negative-type photoresist is used as the photosensitive resin material forming the application film 300, in the exposure treatment, the photomask used is configured to expose a pattern portion where the application film 300 is to remain and to shield an unnecessary portion where the application film 300 is to be removed. In this case, the region of the application film 300 where the first partition wall 12 and the first spacers 16 are formed is exposed to light and the other region is exposed.

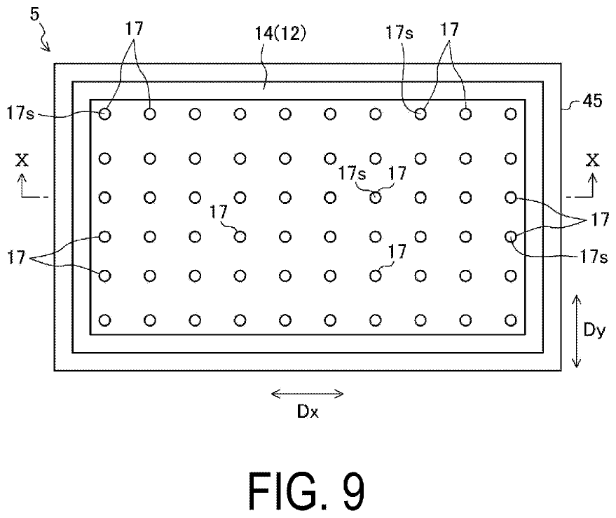

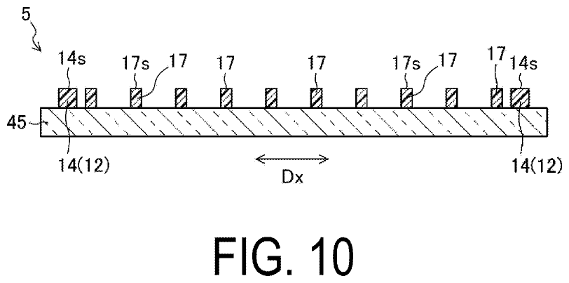

Subsequently, the application film 300 subjected to the exposure treatment is subjected to post-exposure baking to complete the photosensitive reaction of the photosensitive resin material forming the application film 300. Subsequently, a development treatment is performed on the application film 300 in which the photosensitive reaction is completed. In the development treatment, an alkaline developing solution such as tetramethylammonium hydroxide (TMAH) or potassium hydroxide (KOH) is used to dissolve an unnecessary portion of the application film 300 and leave only a pattern portion of the application film 300. Then, after cleaning with pure water, the substrate with the application film 300 partially left thereon is post-baked at a predetermined temperature to evaporate the solvent remaining on the substrate and completely cure the photoresist. In this manner, as illustrated in FIGS. 9 and 10, the second partition wall 14 and the plurality of second spacers 17 are formed on the base substrate 45.

In this manner, the counter substrate 5 is prepared.

### Bonding Process

In the bonding process, the array substrate 3 and the counter substrate 5 are bonded together. In order to bond the array substrate 3 and the counter substrate 5 to one another, first, the dam member 9 and the fill member 11 are applied to one of the array substrate 3 and the counter substrate 5.

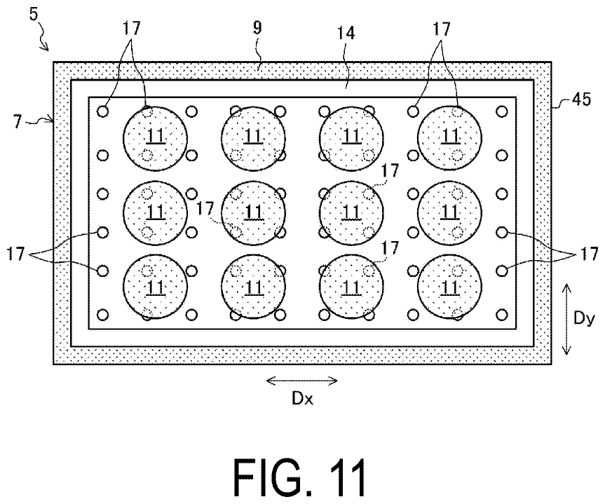

In the present example, as illustrated in FIG. 11, the uncured dam member 9 is applied in a frame shape to the outer periphery of the second partition wall 14 of the counter substrate 5. In addition, a predetermined amount of uncured fill member 11 is dropped on the region of the counter substrate 5 surrounded by the second partition wall 14 using a dispenser. The viscosity of the uncured fill member 11 is lower than the viscosity of the uncured dam member 9. As the dam member 9 and the fill member 11, a delayed curing type of organic resin material may be used which requires a predetermined amount of time from irradiation with ultraviolet light to curing. The delayed curing type of organic resin material has a characteristic that its viscosity increases gradually after being irradiated with ultraviolet light.

Subsequently, the organic resin material forming the dam member 9 and the fill member 11 applied to the counter substrate 5 is irradiated with ultraviolet light. Subsequently, the array substrate 3 and the counter substrate 5 are introduced into a vacuum chamber. The interior of the vacuum chamber is evacuated to a vacuum state. Here, it is sufficient that the vacuum state is sufficient for the array substrate 3 and the counter substrate 5 to be pressurized by atmospheric pressure and the fill member 11 to fill uniformly between both substrates 3 and 5 when the panel body PL formed by bonding together the array substrate 3 and the counter substrate 5 is taken out from the vacuum chamber.

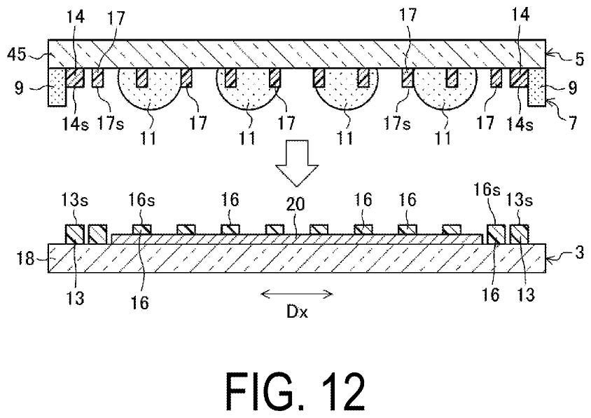

Then, as illustrated in FIG. 12, the array substrate 3 and the counter substrate 5 are arranged in a facing positional relationship in the vacuum chamber. At this time, the first partition wall 13 and the second partition wall 14 are opposed to one another, and the first spacers 16 and the second spacers 17 are opposed to one another. Further, the array substrate 3 and the counter substrate 5 are brought relatively close to one another so that the first partition wall 13 and the second partition wall 14 abut against one another and the first spacers 16 and the second spacers 17 abut against one another. In this manner, the array substrate 3 and the counter substrate 5 are bonded to one another via the dam member 9 and the fill member 11 to form the panel body PL. The array substrate 3 and the counter substrate 5 are bonded to one another while the dam member 9 and the fill member 11 are uncured.

Next, the panel body PL is taken out from the vacuum chamber. As a result, the array substrate 3 and the counter substrate 5 are pressed together by the atmospheric pressure. Accordingly, the fill member 11 spreads between the array substrate 3 and the counter substrate 5 and fills the inside of the partition wall 12 to every corner. The gap between the array substrate 3 and the counter substrate 5 is maintained by the partition wall 12 and the plurality of spacers 15. Thereafter, the dam member 9 and the fill member 11 are completely cured. Here, in order to completely cure the dam member 9 and the fill member 11, the dam member 9 and the fill member 11 may be additionally irradiated with ultraviolet light, or the panel body PL may be heated. Thus, the array substrate 3 and the counter substrate 5 are bonded to one another by the sealing member 7 (the dam member 9 and the fill member 11).

### Additional Process

In the additional process, a protective film (not illustrated) is attached to the front and the back faces of the panel body PL. Also, in the additional process, the wiring line substrate CB is connected to the terminal region TA of the panel body PL using conductive material such as an anisotropic conductive film (ACF) or an anisotropic conductive paste (ACP). In this manner, a display control circuit such as a source driver is mounted on the panel body PL by a chip-on-film (COF) method.

Thus, the organic EL display device 1 is manufactured.

### Advantages of First Embodiment

In the organic EL display device 1 according to the first embodiment, the partition wall 12 and the plurality of spacers 15 are provided in the panel body PL. The partition wall 12 partitions the dam member 9 and the fill member 11. According to this configuration, when the array substrate 3 and the counter substrate 5 are bonded to one another in the manufacture of the organic EL display device 1, the fill member 11 spreading to the outer peripheral side of the panel body PL is blocked by the partition wall 12. Thus, the dam member 9 is prevented from being pushed out from the inside by the fill member 11, and the dam member 9 can be suppressed from breaking. Also, the gap between the array substrate 3 and the counter substrate 5 is maintained by the partition wall 12 and the plurality of spacers 15. Thus, the volume of the sealed space Sc filled with the fill member 11 is constant. Accordingly, the amount of the fill member 11 with respect to the sealed space Sc can be set to an appropriate amount. This can also suppress breakage of the dam member 9 due to the fill member 11. Further, it is possible to reduce air bubble formation in the sealed space Sc. Thus, in the organic EL display device 1, it is possible to suppress the impairment of the sealing properties of the organic EL element 30 from the dam fill structure.

In the organic EL display device 1 of the first embodiment, the partition wall 12 of the present example is formed in a closed frame shape extending around the entire periphery of the frame region FA. Thus, it is possible to prevent the fill member 11 from pushing out the dam member 9 from the inside over the entire periphery of the frame region FA. This is advantageous for preventing the dam member 9 from being broken.

In the organic EL display device 1 according to the first embodiment, the partition wall 12 is provided at least on the counter substrate 5. The dam member 9 and the fill member 11 are applied to the counter substrate 5 provided with the partition wall 12. Thus, irradiation of ultraviolet light for curing the dam member 9 and the fill member 11 is performed on the counter substrate 5. Although there is a concern that irradiation of the array substrate 3 with ultraviolet light may damage the TFTs 25 and the organic EL elements 30, according to the present example, since the counter substrate 5 is irradiated with ultraviolet light, it is possible to reduce damage caused by ultraviolet light to the TFTs 25 and the organic EL elements 30 in the array substrate 3.

In the organic EL display device 1 according to the first embodiment, the first partition wall 13 of the array substrate 3 and the second partition wall 14 of the counter substrate 5 are butted against one another. The first spacers 16 of the array substrate 3 and the second spacers 17 of the counter substrate 5 are butted against one another. As described above, when the partition wall 12 and the spacers 15 are separately provided on the array substrate 3 and the counter substrate 5, the height of the partition wall 12 is determined by the combination of the first partition wall 13 and the second partition wall 14, and the height of the spacers 15 is determined by the combination of the first spacers 16 and the second spacers 17. Thus, it is easy to ensure the thickness of the sealing member 7 as compared with the case where the partition wall 12 and the spacers 15 are provided only on the array substrate 3 or only on the counter substrate 5. In addition, it is possible to suppress variations in the height of the partition wall 12 and the height of the spacers 15, and to accurately manage the volume of the sealed space Sc.

In the organic EL display device 1 according to the first embodiment, the area of the abutting face 16s of the first spacer 16 of the array substrate 3 is larger than the area of the abutting face 17s of the second spacer 17 of the counter substrate 5. As described above, when the areas of the abutting faces 16s and 17s of the first spacer 16 and the second spacer 17 are different from one another, even if the relative positions of the array substrate 3 and the counter substrate 5 are slightly offset when the array substrate 3 and the counter substrate 5 are bonded to one another, the second spacer 17 and the first spacer 16 can be abutted against one another. Thus, a slight positional offset is allowed between the array substrate 3 and the counter substrate 5, and it is not necessary to have strict accuracy for the positioning of the substrates 3 and 5.

In the organic EL display device 1 according to the first embodiment, the first partition wall 13 and the first spacers 16 are formed of the same material of the edge cover 40 and in the same layer on the array substrate 3. According to this configuration, in the manufacture of the array substrate 3, the first partition wall 13 and the first spacers 16 are formed together with the edge cover 40 in the same process. Thus, the number of processes required for manufacturing the array substrate 3 can be reduced as compared with a case where the first partition wall 13 and the first spacers 16 are formed in a process different from the process of forming the edge cover 40.

### Second Embodiment

The organic EL display device 1 according to the second embodiment differs from that of the first embodiment in terms of the configuration of the partition wall 12. Note that in the following embodiments, the organic EL display device 1 is configured in a similar manner to the first embodiment described above except that the configuration of the partition wall 12 is different from that of the first embodiment described above. Thus, only the partition wall 12 having the different configuration is described, and portions with the same configuration are as in the first embodiment and will not be described in detail.

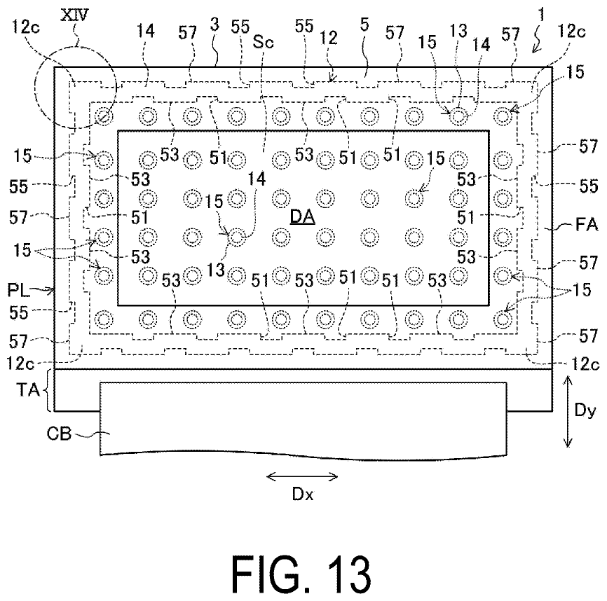

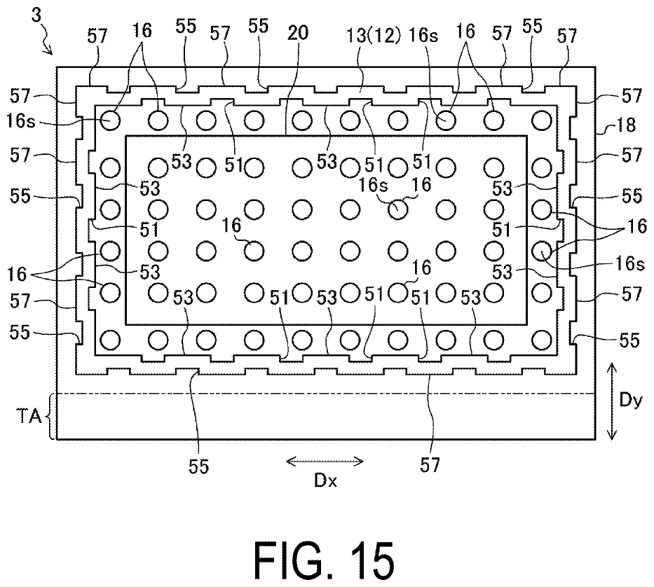

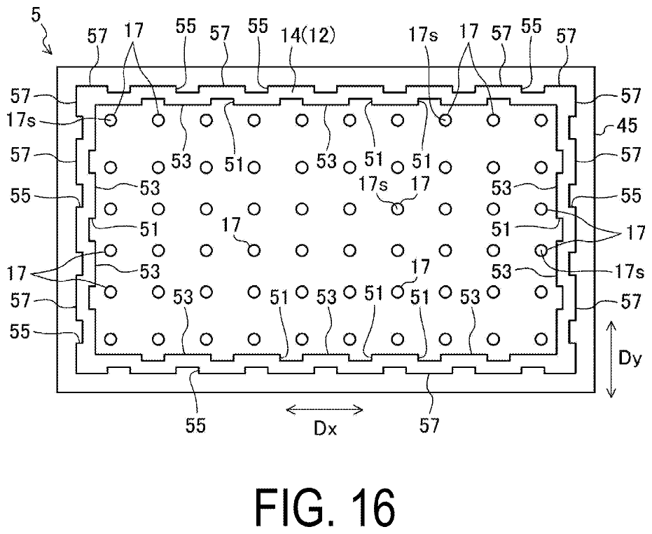

As illustrated in FIG. 13, in the organic EL display device 1 according to the second embodiment, the partition wall 12 is formed in a rectangular frame-like shape extending non-linearly in a crank-like shape around the entire periphery. As illustrated in FIGS. 15 and 16, the first partition wall 13 provided on the array substrate 3 and the second partition wall 14 provided on the counter substrate 5 are formed in the same shape as the partition wall 12 described above and are abutted against one another over the entire periphery.

The inner peripheral surface of the partition wall 12 is formed with an uneven shape. The uneven shape of the inner peripheral surface of the partition wall 12 includes recessed portions 51 and protruding portions 53 alternately arranged in the circumferential direction of the partition wall 12. The fill member 11 is also filled inside the recessed portions 51 forming the uneven shape of the inner peripheral surface of the partition wall 12. The outer peripheral surface of the partition wall 12 is also formed with an uneven shape. The uneven shape of the outer peripheral surface of the partition wall 12 includes recessed portions 55 and protruding portions 57 alternately arranged in the circumferential direction of the partition wall 12. The dam member 9 enters the inner side of the recessed portions 55 forming the uneven shape of the outer peripheral surface of the partition wall 12.

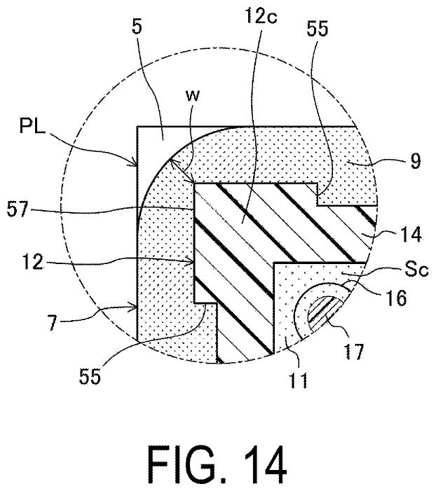

The partition wall 12 of the present example is formed in a rectangular frame-like shape. Thus, as illustrated in FIG. 14, a width w of the dam member 9 is narrower at corner portions 12c of the partition wall 12. In addition, in the manufacture of the organic EL display device 1, when the array substrate 3 and the counter substrate 5 are bonded to one another, the fill member 11 extending to the outer peripheral side of the sealed space Sc reaches the corner portions 12c of the partition wall 12 in the final stage. Also, the space at the corner portions 12c of the partition wall 12 is narrow. Thus, it is difficult to fill the corner portions 12c with the fill member 11, and air bubbles tend to be formed.

When the width of the dam member 9 is narrow on the outer side of the corner portions 12c of the partition wall 12 and air bubbles are formed in the fill member 11 on the inner side of the corner portions 12c, the sealing properties of the organic EL element 30 from the dam fill structure may be impaired. However, in the present example, the recessed portions 51 forming the uneven shape of the inner peripheral surface of the partition wall 12 is provided as a portion where the fill member 11 reaches the final stage when the array substrate 3 and the counter substrate 5 are bonded to one another. Accordingly, even if air bubbles are formed in the fill member 11, the bubbles can be located at positions away from the corner portions 12c of the partition wall 12.

### Advantages of Second Embodiment

In the organic EL display device 1 of the second embodiment, the outer peripheral surface of the partition wall 12 is formed with an uneven shape. The dam member 9 also enters the inner side of the recessed portions 55 forming the uneven shape of the outer peripheral surface of the partition wall 12. Accordingly, the contact area between the partition wall 12 and the dam member 9 is increased, and the bonding strength between the array substrate 3 and the counter substrate 5 by the dam member 9 can be improved.

In the organic EL display device 1 of the second embodiment, the inner peripheral surface of the partition wall 12 is formed with an uneven shape. The fill member 11 is also filled inside the recessed portions 51 forming the uneven shape of the inner peripheral surface of the partition wall 12. Accordingly, the contact area between the partition wall 12 and the fill member 11 is increased, and the bonding strength between the array substrate 3 and the counter substrate 5 by the fill member 11 can be improved.

In addition, when air bubbles are formed in the fill member 11, the recessed portions 51 forming the uneven shape of the inner peripheral surface of the partition wall 12 function as a place for the air bubbles to escape. Accordingly, the formation of air bubbles in the fill member 11 on the inner side of the corner portions 12c of the partition wall 12 can be suppressed. This is advantageous in that the formation of air bubbles in the fill member 11 does not impair the sealing properties of the organic EL elements 30 from the dam fill structure and the width of the dam member 9 on the outer sides of the corner portions 12c portions of the partition wall 12 can be reduced.

### Third Embodiment

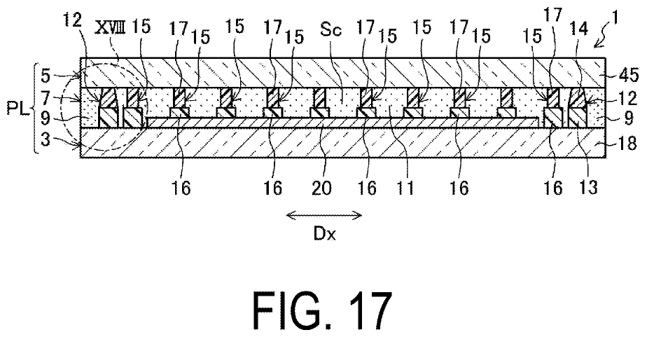

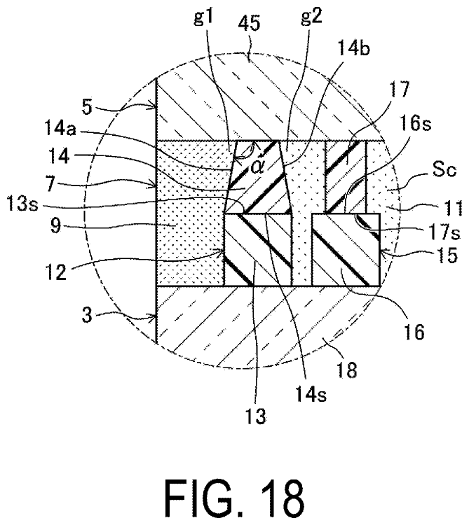

As illustrated in FIGS. 17 and 18, in the organic EL display device 1 according to the third embodiment, the second partition wall 14 is formed on the counter substrate 5 with a reverse tapered cross section. The term “reverse tapered cross section” used herein refers to a shape in which the width of the second partition wall 14 on the side closer to the base substrate 45 is narrow and an angle α formed by the bottom face and the side faces in the width direction of the second partition wall 14 is 90° or greater.

The width of the bottom face of the second partition wall 14 is less than the width of the abutting face 14s of the second partition wall 14. The width of the abutting face 14s of the second partition wall 14 is equal to the width of the abutting face 13s of the first partition wall 13 provided on the array substrate 3. The second partition wall 14 of the present example is formed by adjusting the exposure amount or development time so that the lower portion of the pattern portion is removed when the application film 300 is patterned by photolithography.

The dam member 9 enters a gap g1 formed by a top portion of the second partition wall 14 on the outer peripheral side between the base substrate 45. An inclined side face 14a on the outer peripheral side of the second partition wall 14 is bonded to the dam member 9. Also, the fill member 11 enters a gap g2 formed by a top portion of the second partition wall 14 on the inner peripheral side between the base substrate 45. An inclined side face 14b on the inner peripheral side of the second partition wall 14 is bonded to the fill member 11.

### Advantages of Third Embodiment

In the organic EL display device 1 according to the third embodiment, the second partition wall 14 is formed on the counter substrate 5 with a reverse tapered cross section. Accordingly, the area of the contact portion between the dam member 9 and the base substrate 45 is increased due to the width of the bottom face of the second partition wall 14 being less than the width of the abutting face 14s. Thus, the bonding strength between the array substrate 3 and the counter substrate 5 by the dam member 9 can be improved. In addition, in the manufacture of the organic EL display device 1, when the array substrate 3 and the counter substrate 5 are bonded to one another and the fill member 11 extending to the outer peripheral side of the sealed space Sc reaches the second partition wall 14, the fill member 11 enters the gap g2 between the top portion of the second partition wall 14 and the base substrate 45. Thus, the first partition wall 13 and the second partition wall 14 can be butted against one another before the fill member 11 runs up over the second partition wall 14. If the fill member 11 runs up over the second partition wall 14, the speed of the fill member 11 increases when the fill member 11 passes through the narrow gap between the abutting face 13s of the first partition wall 13 and the abutting face 14s of the second partition wall 14 before abutting, and the dam member 9 may be broken. The above-described configuration of the present example is advantageous in suppressing breakage of the dam member 9.

### Fourth Embodiment

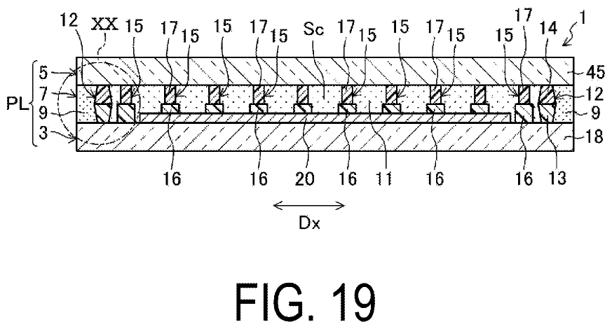

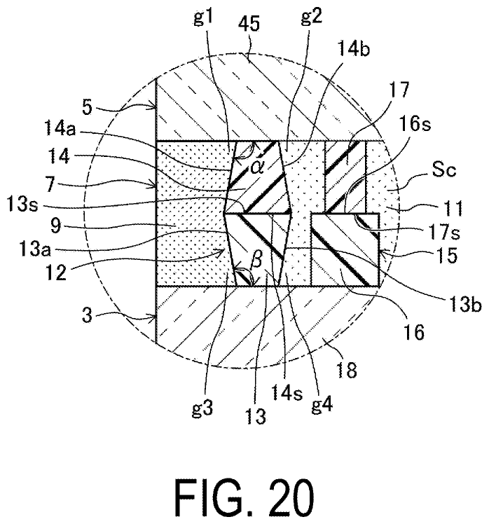

As illustrated in FIGS. 19 and 20, in the organic EL display device 1 according to the fourth embodiment, the first partition wall 13 is formed on the array substrate 3 with a reverse tapered cross section. The term “reverse tapered cross section” used herein refers to a shape in which the width of the first partition wall 13 on the side closer to the base substrate 18 is narrow and an angle β formed by the bottom face and the side faces in the width direction of the first partition wall 13 is 90° or greater.

The width of the bottom face of the first partition wall 13 is less than the width of the abutting face 13s of the first partition wall 13. As in the third embodiment, the second partition wall 14 is formed on the counter substrate 5 with a reverse tapered cross section. The width of the abutting face 14s of the second partition wall 14 and the width of the abutting face 13s of the first partition wall 13 provided on the array substrate 3 are the same. The first partition wall 13 of the present example is formed by adjusting the exposure amount or development time so that the lower portion of the pattern is removed when the application film 100 is patterned by photolithography.

The dam member 9 enters a gap g3 formed by a top portion of the first partition wall 13 on the outer peripheral side between the base substrate 18. An inclined side face 13a on the outer peripheral side of the first partition wall 13 is bonded to the dam member 9. Also, the fill member 11 enters a gap g4 formed by a top portion of the first partition wall 13 on the inner peripheral side between the base substrate 18. An inclined side face 13b on the inner peripheral side of the first partition wall 13 is bonded to the fill member 11. The relationship between the dam member 9 and the fill member 11 and the second partition wall 14 is the same as that in the third embodiment.

### Advantages of Fourth Embodiment

In the organic EL display device 1 according to the fourth embodiment, the first partition wall 13 is formed on the array substrate 3 with a reverse tapered cross section. Accordingly, the area of the contact portion between the dam member 9 and the base substrate 18 is increased due to the width of the bottom face of the first partition wall 13 being less than the width of the abutting face 13s. Thus, the bonding strength between the array substrate 3 and the counter substrate 5 by the dam member 9 can be improved. With respect to the second partition wall 14, effects similar to those of the third embodiment can be obtained.

### Fifth Embodiment

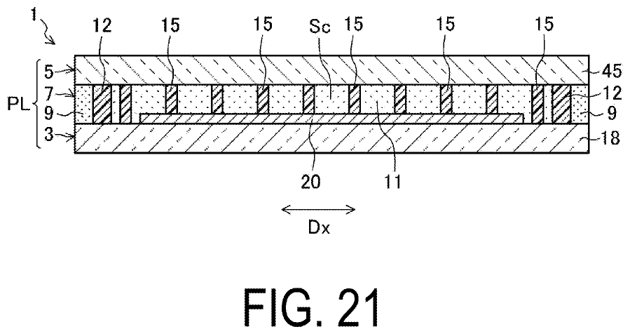

As illustrated in FIG. 21, in the organic EL display device 1 according to the fifth embodiment, the partition wall 12 and the plurality of spacers 15 are provided only on the counter substrate 5. The partition wall 12 is located at a position similar to that of the second partition wall 14 of the first embodiment. Each spacer 15 is located at a position similar to that of the second spacer 17 of the first embodiment. The partition wall 12 and each spacer 15 abut against the face of the array substrate 3.

The partition wall 12 and each spacer 15 located at the frame region FA and each spacer 15 located at the display region DA have different heights on the counter substrate 5. The partition wall 12 and each spacer 15 of the frame region FA are relatively high, and each spacer 15 of the display region DA is relatively low. The height difference between the partition wall 12 and each spacer 15 of the frame region FA and each spacer 15 of the display region DA corresponds to the thickness of the element layer 20 and is realized by using a graytone mask or a halftone mask.

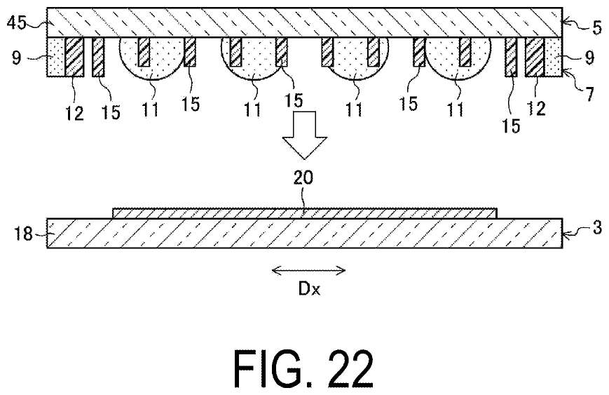

In the manufacture of the organic EL display device 1 of the present example, as illustrated in FIG. 22, the dam member 9 and the fill member 11 may be applied to the counter substrate 5 in the same manner as in the first embodiment. Then, the array substrate 3 and the counter substrate 5 may be bonded to one another via the dam member 9 and the fill member 11 after the dam member 9 and the fill member 11 are irradiated with ultraviolet light for starting a curing reaction. According to this configuration, it is possible to reduce damage to the TFTs 25 in the array substrate 3 and the organic EL elements 30 due to ultraviolet light.

### Advantages of Fifth Embodiment

In the organic EL display device 1 according to the fifth embodiment, the partition wall 12 and the plurality of spacers 15 are provided only on the counter substrate 5. According to this configuration, when the gap between the array substrate 3 and the counter substrate 5 is the same, the height of the partition wall 12 provided on the counter substrate 5 is higher than that in a case where the partition wall 12 and the spacers 15 are separately provided on the array substrate 3 and the counter substrate 5. Thus, in the manufacture of the organic EL display device 1, when the array substrate 3 and the counter substrate 5 are bonded to one another, it is possible to suppress the fill member 11 from running up over the partition wall 12.

### Sixth Embodiment

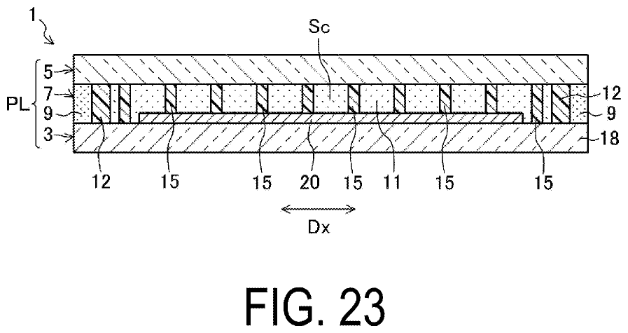

As illustrated in FIG. 23, in the organic EL display device 1 according to the sixth embodiment, the partition wall 12 and the plurality of spacers 15 are provided only on the array substrate 3. The partition wall 12 is located at a position similar to that of the first partition wall 13 of the first embodiment. Each spacer 15 is located at a position similar to that of the first spacer 16 of the first embodiment. The partition wall 12 and each spacer 15 abut against the face of the counter substrate 5. The counter substrate 5 of the present example is formed of a plate body corresponding to the base substrate 45 of the first embodiment.

The partition wall 12 and each spacer 15 located at the frame region FA and each spacer 15 located at the display region DA have different heights. An abutting face 12s of the partition wall 12 and an abutting face 15s of each spacer 15 are aligned at the same height position in a planar direction orthogonal to the thickness direction of the array substrate 3. The height difference between the partition wall 12 and each spacer 15 of the frame region FA and each spacer 15 of the display region DA corresponds to the thickness of the element layer 20 and is realized by using a graytone mask or a halftone mask.

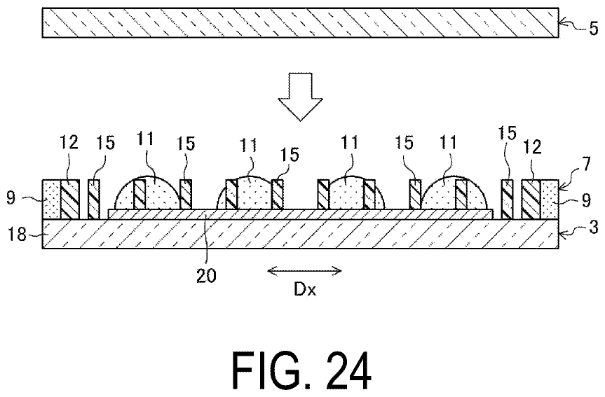

In the manufacture of the organic EL display device 1 of the present example, as illustrated in FIG. 24, the dam member 9 and the fill member 11 may be applied to the array substrate 3. Then, the array substrate 3 and the counter substrate 5 may be bonded to one another via the dam member 9 and the fill member 11 after the dam member 9 and the fill member 11 are subjected to irradiation with ultraviolet light or heat treatment for starting the curing reaction.

### Advantages of Sixth Embodiment

In the organic EL display device 1 according to the sixth embodiment, the partition wall 12 and the plurality of spacers 15 are provided only on the array substrate 3. According to this configuration, when the gap between the array substrate 3 and the counter substrate 5 is the same, the height of the partition wall 12 provided on the array substrate 3 is higher than that in a case where the partition wall 12 and the spacers 15 are separately provided on the array substrate 3 and the counter substrate 5. Thus, in the manufacture of the organic EL display device 1, when the array substrate 3 and the counter substrate 5 are bonded to one another, it is possible to suppress the organic resin material forming the fill member 11 from running up over the partition wall 12.

### First Modified Example

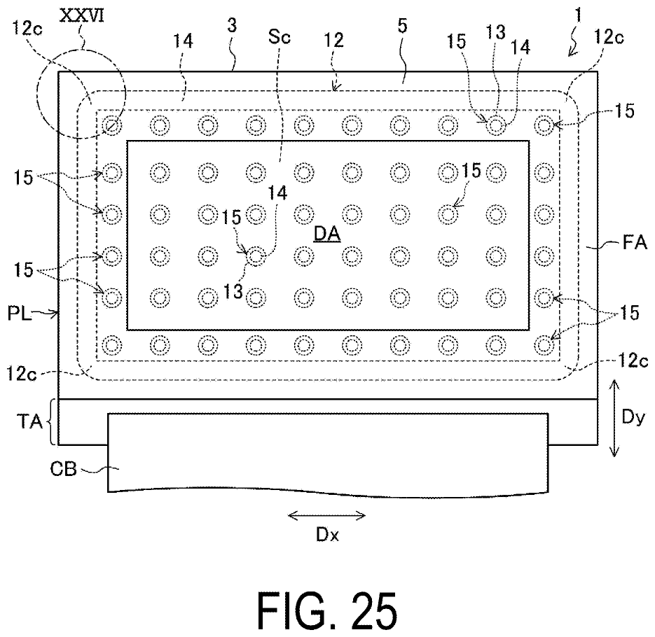

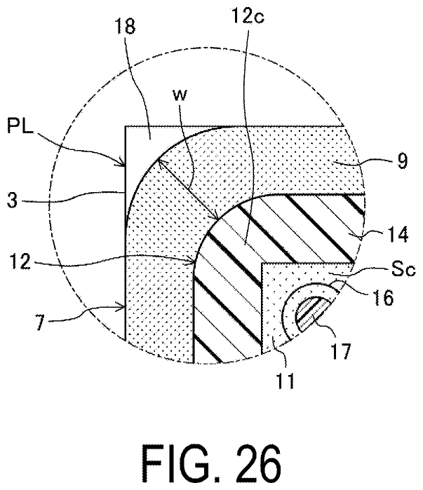

As illustrated in FIG. 25, in the organic EL display devices 1 according to the first to sixth embodiments, the corner portions 12c located at the four corners of the outer peripheral surface of the partition wall 12 may be formed as curved R faces. That is, each corner portion 12c of the partition wall 12 may be chamfered to have a rounded curved shape. As illustrated in FIG. 26, when each corner portion 12c of the partition wall 12 of the present example is formed into an R surface, the widths w of the dam members 9 on the outer side the corner portions 12c can be increased. This is advantageous for enhancing the sealing properties of the organic EL element 30 from the dam fill structure.

### Second Modified Example

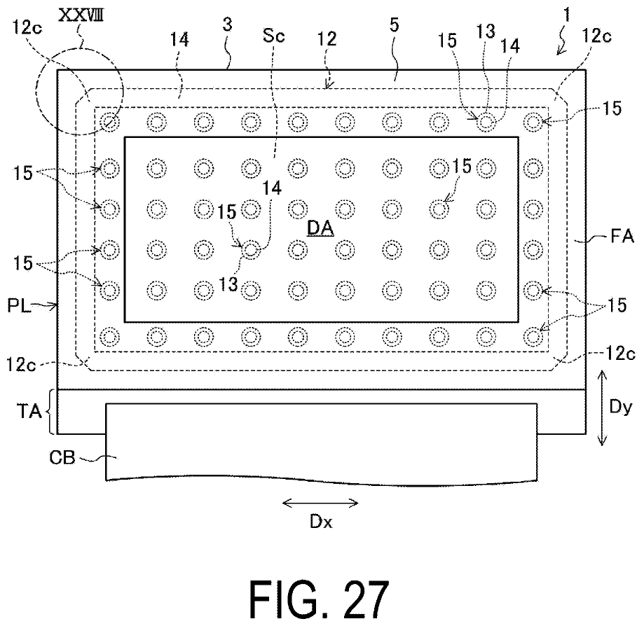

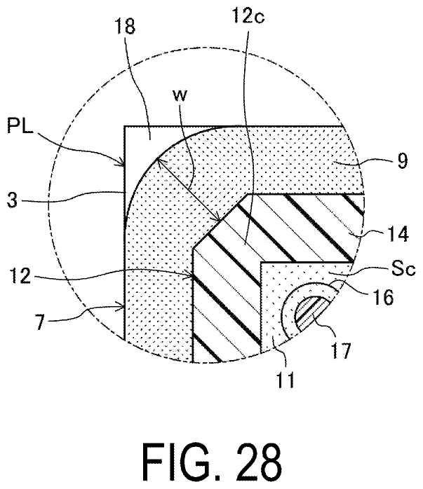

As illustrated in FIG. 27, in the organic EL display device 1 according to the first to sixth embodiments, the corner portions 12c of the outer peripheral surface of the partition wall 12 may be formed as inclined C faces inclined with respect to the two sides of the partition wall 12 forming the corner portion 12c. That is, each corner portion 12c of the partition wall 12 may be chamfered to have a cut planar shape. As illustrated in FIG. 28, when each corner portion 12c of the partition wall 12 of the present example is formed into a C surface, the widths w of the dam members 9 on the outer side the corner portions 12c can be increased. This is advantageous for enhancing the sealing properties of the organic EL element 30 from the dam fill structure.

### Other Embodiments

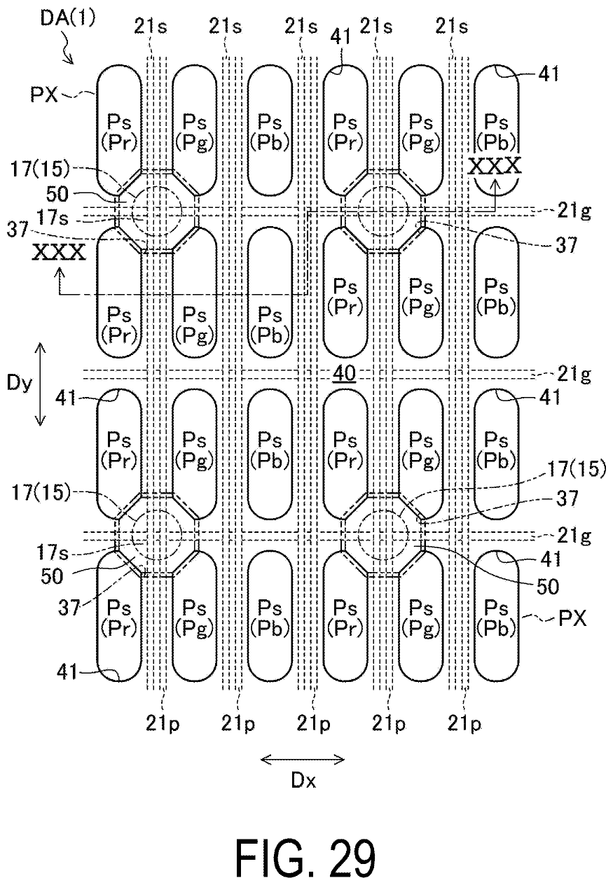

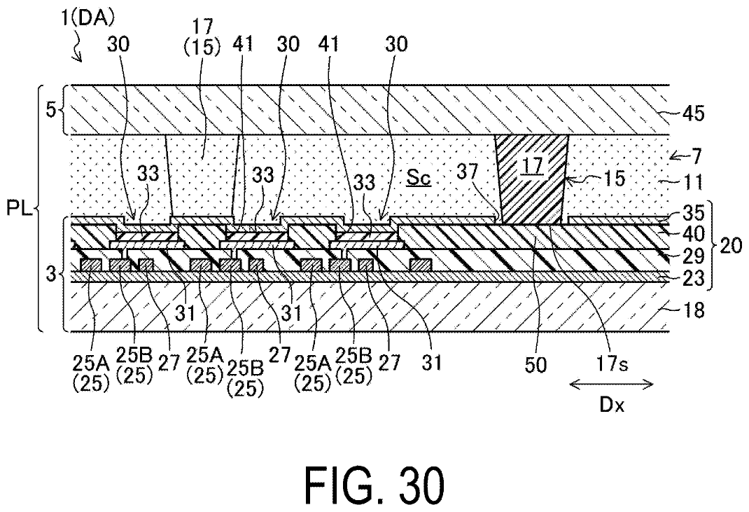

In the first embodiment, each spacer 15 located in the display region DA includes the first spacer 16 provided on the array substrate 3 and the second spacer 17 provided on the counter substrate 5, but no such limitation is intended. As illustrated in FIGS. 29 and 30, the array substrate 3 may be provided with seat portions 50 functioning as seating faces of the second spacers 17 instead of the first spacers 16 located in the display region DA. The seat portions 50 are integrally formed with the edge cover 40 at the same height as the edge cover 40.

In the first embodiment described above, the first partition wall 13 of the array substrate 3 is formed of the same material as the edge cover 40 and in the same layer, but no such limitation is intended. The first partition wall 13 may include a first wall layer formed of the same material and in the same layer as an insulating film other than the edge cover 40 included in the element layer 20 and a second wall layer formed of the same material and in the same layer as the edge cover 40.

In the first embodiment, although the partition wall 12 is formed in a closed frame-like shape, no such limitation is intended. The partition wall 12 may be provided only in a portion of the frame region FA. For example, the partition wall 12 may be provided in contact with only a portion of the dam member 9 which is likely to be broken in accordance with the dropping position of the fill member 11 or the like.

In the first embodiment, the area of the abutting face 16s of the first spacer 16 is larger than the area of the abutting face 17s of the second spacer 17. However, no such limitation is intended. For example, the area of the abutting face 17s of the second spacer 17 may be larger than the area of an abutting face 16s of the first spacer 16. Even with this configuration, a slight positional offset is allowed between the array substrate 3 and the counter substrate 5, and it is not necessary to have strict accuracy for the positioning of the substrates 3 and 5. The area of the abutting face 16s of the first spacer 16 and the area of an abutting face 17s of the second spacer 17 may be the same.

In the organic EL display device 1 of the fifth embodiment, the partition wall 12 may be formed with a reverse tapered cross section similar to that of the second partition wall 14 of the third embodiment. With this configuration, effects similar to those of the third embodiments can be obtained. Also, in the organic EL display device 1 of the sixth embodiment, the partition wall 12 may be formed with a reverse tapered cross section similar to that of the first partition wall 13 of the fourth embodiment. With this configuration, effects similar to those of the third embodiments can be obtained.

In the organic EL display device 1 according to the first to sixth embodiments, one of either the partition wall 12 or the plurality of spacers 15 may be provided on the array substrate 3 and the other may be provided on the counter substrate 5. For example, the plurality of spacers 15 may be provided on the array substrate 3, and the partition wall 12 may be provided on the counter substrate 5.

As described above, the preferred embodiments are described as examples of the technique of the disclosure. However, the technique of the disclosure is not limited to the embodiments and the modified examples, and is also applicable to an embodiment in which modification, replacement, adding, omission, and the like are suitably made. It is understood by those skilled in the art that various modified examples can be made to the above embodiment without departing from the spirit of the technology of the disclosure, and such modified examples also belong to the scope of the technology of the disclosure.

For example, in the first to sixth embodiments, the organic EL layer 33 is provided in the individual subpixels Ps, but no limitation is intended. The organic EL layer 33 may be continuously provided in common in the plurality of subpixels Ps. In this case, the organic EL display device 1 may include a color filter, for example, to perform color tone expression of each of the subpixels Ps.

In the first to sixth embodiments, each pixel PX is constituted by the subpixels Pr, Pg, and Pb of three colors, but no such limitation is intended. The subpixels Ps constituting each of the pixels PX are not limited to having the three colors, and may have four or more colors. The subpixels Pr, Pg, and Pb of three colors constituting each pixel PX are provided adjacent to one another in the row direction Dx, but no such limitation is intended. The subpixels Ps of three colors constituting each pixel PX may be three subpixels Ps in a delta arrangement positional relationship or may be arranged in other manners.

In the first to sixth embodiments, the TFTs 25 provided in each subpixel Ps include the two TFTs 25, the first TFT 25A and the second TFT 25B. However, no such limitation is intended. The number of TFTs 25 provided in each subpixel Ps may be three or more. In addition, the direction in which the gate lines 21g, the source lines 21s, and the power source lines 21p extend may be switched, that is, the gate lines 21g may extend in the column direction Dy, and the source lines 21s and the power source lines 21p may extend in the row direction Dx.

In first to sixth embodiments, the organic EL elements 30 are configured as top-emitting types, but no such limitation is intended. The organic EL elements 30 may be configured as bottom-emitting types in which light emitted from the organic EL layer 33 is extracted from the base substrate 18 side. The organic EL elements 30 may be configured as double-sided light emitting types in which light emitted from the organic EL layer 33 is extracted from both the base substrate 18 side and the counter substrate 5 side.

In the first to sixth embodiments, the organic EL layer 33 has a five-layer structure including the hole injection layer, the hole transport layer, the light-emitting layer, the electron transport layer, and the electron injection layer, but no such limitation is intended. The organic EL layer 33 may have a three-layer structure including a hole injection layer and hole transport layer, a light-emitting layer, and an electron transport layer and electron injection layer, and can adopt any chosen layered structure.

In the first to sixth embodiments, the organic EL display device 1 has been exemplified as a display device, but no such limitation is intended. The technology of the disclosure can be applied to a display device including a plurality of light-emitting elements driven by a current, for example. Examples of the display device include a display device including a quantum-dot light-emitting diode (QLED), which is a light-emitting element using a quantum dot-including layer.

### INDUSTRIAL APPLICABILITY

As described above, the disclosure is useful for a display device.

### REFERENCE SIGNS LIST

DA Display region
FA Frame region
PL Panel body
1 Organic EL display device (display device)
3 Array substrate (first substrate)
5 Counter substrate (second substrate)
7 Sealing member
9 Dam member
11 Fill member
12 Partition wall
13 First partition wall (partition wall of first substrate)
14 Second partition wall (partition wall of second substrate)
15 Spacer
16 First spacer (spacer of first substrate)
16s Abutting face of first spacer
17 Second spacer (spacer of second substrate)
17s Abutting face of second spacer
30 Organic EL element (light-emitting element)
40 Edge cover
51 Recessed portion
53 Protruding portion
55 Recessed portion
57 Protruding portion

1. A display device comprising:
a first substrate provided with a plurality of light-emitting elements;
a second substrate disposed facing the first substrate; and
a sealing member configured to bond together the first substrate and the second substrate and seal the plurality of light-emitting elements,
wherein a display region configured to display an image by light emission of the plurality of light-emitting elements and a frame region provided on an outer side of the display region are provided,
the sealing member includes, between the first substrate and the second substrate, a dam member disposed in the frame region surrounding the display region and a fill member filling the space surrounded by the dam member, and
a panel body formed by bonding together the first substrate and the second substrate with the sealing member includes a partition wall configured to partition the dam member and the fill member and a plurality of spacers disposed in a spread-out manner in the display region and configured to maintain a gap between the first substrate and the second substrate.

2. The display device according to claim 1,
wherein the partition wall is formed in a closed frame-like shape extending around an entire periphery of the frame region.

3. The display device according to claim 2,
wherein an inner peripheral surface of the partition wall is formed with an uneven shape.

4. The display device according to claim 3,
wherein the uneven shape of the inner peripheral surface of the partition wall includes recessed portions and protruding portions alternately arranged in a circumferential direction of the partition wall.

5. The display device according to claim 1,
wherein an outer peripheral surface of the partition wall is formed with an uneven shape.

6. The display device according to claim 5,
wherein the uneven shape of the outer peripheral surface of the partition wall includes recessed portions and protruding portions alternately arranged in a circumferential direction of the partition wall.

7. The display device according to claim 1,
wherein the partition wall is provided at least on the second substrate.

8. The display device according to claim 7,
wherein the partition wall is provided separately on the first substrate and the second substrate, and
the partition wall of the first substrate and the partition wall of the second substrate abut one another in a direction in which the first substrate and the second substrate face one another.

9. The display device according to claim 1,
wherein the plurality of spacers are provided on the first substrate provided with the partition wall and/or the second substrate provided with the partition wall.

10. The display device according to claim 1,
wherein the plurality of spacers are provided separately on the first substrate and the second substrate, and
the plurality of spacers of the first substrate and the plurality of spacers of the second substrate abut one another in a direction in which the first substrate and the second substrate face one another.

11. The display device according to claim 10,
wherein of the plurality of spacers of the first substrate and the plurality of spacers of the second substrate, an area of each abutting face of each of one of the plurality of spacers is greater than an area of each abutting face of each of the other one of the plurality of spacers.

12. The display device according to claim 1,
wherein each of the plurality of light-emitting elements includes an electrode individually,
the first substrate includes an edge cover to partition a plurality of the electrodes, and
the partition wall and the plurality of spacers are formed on the first substrate of an identical material and in an identical layer as the edge cover.

13. The display device according to claim 1,
wherein the partition wall is formed in a rectangular frame-like shape, and
a corner portion of an outer peripheral surface of the partition wall is formed as an R surface curved or a C surface inclined with respect to two sides of the partition wall forming the corner portion.

14. The display device according to claim 1,
wherein the partition wall is formed with a reverse tapered cross section on the first substrate and/or the second substrate.

15. The display device according to claim 1,
wherein each of the plurality of light-emitting elements is an organic electroluminescence element or a quantum dot light emitting diode.
